(19) United States
(12) Patent Application Publication
(10) Pub. No.: US 2025/0254905 A1
(43) Pub. Date: Aug. 7, 2025

(54) TRENCH-SHAPED TERNARY CMOS DEVICE

(71) Applicant: UIF (University Industry Foundation), Yonsei University, Seoul (KR)

(72) Inventors: Jiwon Chang, Seoul (KR); Jiwon Ma, Seoul (KR); Changwook Lee, Seoul (KR)

(21) Appl. No.: 18/977,733

(22) Filed: Dec. 11, 2024

(30) Foreign Application Priority Data
Feb. 7, 2024 (KR) 10-2024-0018517
Feb. 7, 2024 (KR) 10-2024-0018518

(51) Int. Cl. H10D 30/47; H10D 62/80; H10D 84/01; H10D 84/85; H10N 70/20

(52) U.S. Cl. CPC H10D 30/485; H10D 62/883; H10D 84/0167; H10D 84/85; H10N 70/231

(57) ABSTRACT

A trench-shaped ternary CMOS device includes a common drain provided at the bottom, a 2D phase change material layer composed of a 2D phase change material and stacked on the top of the common drain, a common gate provided over the 2D phase change material layer, a 2D n-type channel semiconductor material layer that is vertically stacked with respect to the 2D phase change material layer and connected to one end of the 2D phase change material layer and that has one side surface that faces one end of the common gate, and a 2D p-type channel semiconductor material layer that is vertically stacked with respect to the 2D phase change material layer and connected to an opposite end of the 2D phase change material layer and that has one side surface that faces an opposite end of the common gate.

### CROSS-REFERENCE TO RELATED APPLICATIONS

This application claims priority under 35 U.S.C. § 119 to Korean Patent Application No. 10-2024-0018518 filed on Feb. 7, 2024 and Korean Patent Application No. 10-2024-0018517 filed on Feb. 7, 2024, in the Korean Intellectual Property Office, the disclosures of which are incorporated by reference herein in their entireties.

### BACKGROUND

Embodiments of the present disclosure described herein relate to a CMOS device for enabling ternary operations.

The present disclosure is derived from the research conducted as part of the personal basic research (Project Identification Number: 1711181765, Project Number: 2022R1A2C2008726, Research Project Title: Research on Monolithic 3D Integrable Ternary CMOS Technology Using Phase Transition Depending on Thickness of 2D Material for Implementation of Logic-in-Memory, Project Management Organization: National Research Foundation of Korea, Project Executing Organization: Yonsei University, Research Period: 2023 Mar. 1˜2024 Feb. 29) of the Ministry of Science and ICT. Meanwhile, the Korean government has no property interest in all aspects of the present disclosure.

A complementary metal-oxide semiconductor (CMOS), which is a type of integrated circuit, is widely used in circuits of most electronic devices. The CMOS is a device having a MOSFET (p-MOS) of a p channel and a MOSFET (n-MOS) of an n channel formed in a single chip and allows the MOS of the p channel and the MOS of the n channel to complementarily operate. The CMOS is mainly used to constitute an integrated circuit such as a microprocessor, a static random access memory (SRAM), an image sensor, or the like. The CMOS is widely used because it is cheaper than a process using a BJT device and is capable of implementing a low-power circuit.

Recently, studies on semiconductor device technology have been widely conducted to address the problem of how much power consumption can be reduced. However, there is a problem that it is difficult to fundamentally solve the power consumption problem in processing of large amounts of information, such as big data, using a binary device that expresses information in the binary system of 0 and 1.

### SUMMARY

Embodiments of the present disclosure provide a trench-shaped ternary CMOS device for performing ternary operations.

Embodiments of the present disclosure provide a trench-shaped ternary CMOS device for increasing a degree of integration by stacking components inside a trench-shaped outer dielectric area.

Embodiments of the present disclosure provide a 2D material-based trench-shaped ternary CMOS device for supporting a wide range of operating speeds so as to be used for various purposes from an ultra-low power environment to a high performance environment.

Embodiments of the present disclosure provide a trench-shaped ternary CMOS device more robustly and stably implemented without a problem of process dispersion due to doping.

Embodiments of the present disclosure provide a trench-shaped ternary CMOS device for increasing the degree of integration of the device using a semiconductor material capable of an upper integration process under a process condition that does not deteriorate Si-based CMOS characteristics and reliability.

Embodiments of the present disclosure provide a vertical sidewall-shaped ternary CMOS device for performing ternary operations.

Embodiments of the present disclosure provide a vertical sidewall-shaped ternary CMOS device for increasing a degree of integration by stacking components inside vertical sidewalls.

Meanwhile, the technical problems to be solved by the present disclosure are not limited to the aforementioned problems, and any other technical problems not mentioned herein will be clearly understood from the following description by those skilled in the art to which the present disclosure pertains.

According to an embodiment, a trench-shaped ternary CMOS device includes a common drain provided at the bottom, a 2D phase change material layer composed of a 2D phase change material and stacked on the top of the common drain, a common gate provided over the 2D phase change material layer, a 2D n-type channel semiconductor material layer that is vertically stacked with respect to the 2D phase change material layer and connected to one end of the 2D phase change material layer and that has one side surface that faces one end of the common gate, and a 2D p-type channel semiconductor material layer that is vertically stacked with respect to the 2D phase change material layer and connected to an opposite end of the 2D phase change material layer and that has one side surface that faces an opposite end of the common gate.

The 2D n-type channel semiconductor material layer may be composed of a 2D semiconductor material having a characteristic of changing into an n-type conductor by a voltage change without separate doping, and the 2D p-type channel semiconductor material layer may be composed of a 2D semiconductor material having a characteristic of changing into a p-type conductor by a voltage change without separate doping.

The 2D phase change material layer may be composed of a 2D phase change material having a characteristic that a band gap is reduced as a thickness of a layer increases.

The 2D phase change material layer may be composed of transition metal dichalcogenides (TDMs) having a characteristic that a band gap is reduced as a thickness of a layer increases.

The 2D phase change material layer may be composed of at least one of platinum diselenide (PtSe₂) or palladium diselenide (PdSe₂).

The 2D phase change material layer may be composed of at least one of arsenene or antimonene. The arsenene may be a 2D phase change material composed of a single element and may have a 2D structure while being an allotrope of arsenic (As), and the antimonene may be a 2D phase change material composed of a single element and may have a 2D structure while being an allotrope of antimony (Sb).

The trench-shaped ternary CMOS device may further include a first source connected to an opposite side surface that faces away from the one side surface of the 2D n-type channel semiconductor material layer that faces the one end of the common gate and a second source connected to an opposite side surface that faces away from the one side surface of the 2D p-type channel semiconductor material layer that faces the opposite end of the common gate.

The 2D phase change material layer may serve as a resistor that limits On-current flowing through the second source, the 2D p-type channel semiconductor material layer, the 2D n-type channel semiconductor material layer, and the first source.

The trench-shaped ternary CMOS device may further include an outer dielectric area having an inner space formed therein in which the 2D phase change material layer, the 2D n-type channel semiconductor material layer, the 2D p-type channel semiconductor material layer, and the common gate are stacked and including the common drain.

The first source may be stacked on an upper surface of one end of the outer dielectric area. The second source may be stacked on an upper surface of an opposite end of the outer dielectric area. The 2D n-type channel semiconductor material layer may be stacked on one inside surface among inside surfaces of the outer dielectric area that face toward the inner space. The 2D p-type channel semiconductor material layer may be stacked on an opposite inside surface among the inside surfaces of the outer dielectric area that face toward the inner space. The 2D phase change material layer may be stacked on an upper surface of the outer dielectric area that faces toward the inner space or an upper surface of the common drain.

The trench-shaped ternary CMOS device may further include a first insulating material layer and a second insulating material layer. The first insulating material layer may be vertically stacked with respect to the 2D phase change material layer so as to be located between the 2D n-type channel semiconductor material layer and the common gate and may be connected to the one end of the common gate, the one side surface of the 2D n-type channel semiconductor material layer that faces the one end of the common gate, and the top of the 2D phase change material layer. The second insulating material layer may be vertically stacked with respect to the 2D phase change material layer so as to be located between the 2D p-type channel semiconductor material layer and the common gate and may be connected to the opposite end of the common gate, the one side surface of the 2D p-type channel semiconductor material layer that faces the opposite end of the common gate, and the top of the 2D phase change material layer.

The 2D phase change material layer may include an intermediate phase change material layer, a first end phase change material layer, and a second end phase change material layer. The intermediate phase change material layer may be stacked on the upper surface of the common drain. The first end phase change material layer may be vertically stacked at one end of the intermediate phase change material layer with respect to the intermediate phase change material layer, may be connected to one end of the 2D n-type channel semiconductor material layer, and may be provided between the first insulating material layer and the one inside surface among the inside surfaces that face toward the inner space of the outer dielectric area. The second end phase change material layer may be vertically stacked at an opposite end of the intermediate phase change material layer with respect to the intermediate phase change material layer, may be connected to one end of the 2D p-type channel semiconductor material layer, and may be provided between the second insulating material layer and the opposite inside surface among the inside surfaces that face toward the inner space of the outer dielectric area.

The trench-shaped ternary CMOS device may further include a first spacer composed of an insulating material, the first spacer being stacked on the top of the 2D phase change material layer and the bottom of the common gate and provided between the first insulating material layer and the second insulating material layer and a second spacer composed of an insulating material, the second spacer being stacked on the top of the common gate and provided between the first insulating material layer and the second insulating material layer.

The trench-shaped ternary CMOS device may further include a CMOS input terminal connected to the common gate and configured such that a common input voltage is input to the common gate and a CMOS output terminal that is connected to the common drain and that outputs a common output voltage.

The CMOS output terminal may output a maximum voltage having a constant magnitude when a voltage input to the CMOS input terminal is less than a first reference voltage, may output an intermediate voltage having a constant magnitude when the voltage input to the CMOS input terminal is greater than or equal to a second reference voltage and less than a third reference voltage, and may output no voltage when the voltage input to the CMOS input terminal is greater than or equal to a fourth reference voltage.

According to an embodiment, a method for manufacturing the trench-shaped ternary CMOS device includes a step of connecting the first source to an upper surface of one end of an outer dielectric area having an inner space formed therein and including the common drain, a step of connecting the second source to an upper surface of an opposite end of the outer dielectric area, a step of depositing the 2D phase change material layer on the top of the outer dielectric area that faces toward the inner space of the outer dielectric area, a step of depositing the 2D n-type channel semiconductor material layer on one inside surface among inside surfaces that face toward the inner space, and a step of depositing the 2D p-type channel semiconductor material layer on an opposite inside surface among the inside surfaces that face toward the inner space.

The method may further include a step of depositing a first spacer composed of an insulating material on the top of the 2D phase change material layer, a step of connecting the common gate to the top of the first spacer, and a step of depositing a second spacer on the top of the common gate.

According to an embodiment, a vertical sidewall-shaped ternary CMOS device includes a common drain provided at the top, a 2D phase change material layer composed of a 2D phase change material and stacked on the bottom of the common drain, a common gate provided under the 2D phase change material layer, a 2D n-type channel semiconductor material layer that is vertically stacked with respect to the 2D phase change material layer and connected to one end of the 2D phase change material layer and that has one side surface that faces one end of the common gate, and a 2D p-type channel semiconductor material layer that is vertically stacked with respect to the 2D phase change material layer and connected to an opposite end of the 2D phase change material layer and that has one side surface that faces an opposite end of the common gate.

The 2D n-type channel semiconductor material layer may be composed of a 2D semiconductor material having a characteristic of changing into an n-type conductor by a voltage change without separate doping, and the 2D p-type channel semiconductor material layer may be composed of a 2D semiconductor material having a characteristic of changing into a p-type conductor by a voltage change without separate doping.

The 2D phase change material layer may be composed of a 2D phase change material having a characteristic that a band gap is reduced as a thickness of a layer increases.

The 2D phase change material layer may be composed of transition metal dichalcogenides (TDMs) having a characteristic that a band gap is reduced as a thickness of a layer increases.

The 2D phase change material layer may be composed of at least one of platinum diselenide (PtSe₂) or palladium diselenide (PdSe₂).

The 2D phase change material layer may be composed of at least one of arsenene or antimonene. The arsenene may be a 2D phase change material composed of a single element and may have a 2D structure while being an allotrope of arsenic (As), and the antimonene may be a 2D phase change material composed of a single element and may have a 2D structure while being an allotrope of antimony (Sb).

The vertical sidewall-shaped ternary CMOS device may further include a first source connected to an opposite side surface that faces away from the one side surface of the 2D n-type channel semiconductor material layer that faces the one end of the common gate and a second source connected to an opposite side surface that faces away from the one side surface of the 2D p-type channel semiconductor material layer that faces the opposite end of the common gate.

The 2D phase change material layer may serve as a resistor that limits On-current flowing through the second source, the 2D p-type channel semiconductor material layer, the 2D n-type channel semiconductor material layer, and the first source.

The vertical sidewall-shaped ternary CMOS device may further include an outer dielectric area having an inner space formed therein in which the 2D phase change material layer, the 2D n-type channel semiconductor material layer, the 2D p-type channel semiconductor material layer, and the common gate are stacked and including the common drain.

The first source may be stacked on a lower surface of one end of the outer dielectric area. The second source may be stacked on a lower surface of an opposite end of the outer dielectric area. The 2D n-type channel semiconductor material layer may be stacked on one inside surface among inside surfaces of the outer dielectric area that face toward the inner space. The 2D p-type channel semiconductor material layer may be stacked on an opposite inside surface among the inside surfaces of the outer dielectric area that face toward the inner space. The 2D phase change material layer may be stacked on a lower surface of the outer dielectric area that faces toward the inner space or a lower surface of the common drain.

The vertical sidewall-shaped ternary CMOS device may further include a first insulating material layer and a second insulating material layer. The first insulating material layer may be vertically stacked with respect to the 2D phase change material layer so as to be located between the 2D n-type channel semiconductor material layer and the common gate and may be connected to the one end of the common gate, the one side surface of the 2D n-type channel semiconductor material layer that faces the one end of the common gate, and the bottom of the 2D phase change material layer. The second insulating material layer may be vertically stacked with respect to the 2D phase change material layer so as to be located between the 2D p-type channel semiconductor material layer and the common gate and may be connected to the opposite end of the common gate, the one side surface of the 2D p-type channel semiconductor material layer that faces the opposite end of the common gate, and the bottom of the 2D phase change material layer.

The 2D phase change material layer may include an intermediate phase change material layer, a first end phase change material layer, and a second end phase change material layer. The intermediate phase change material layer may be stacked on the lower surface of the common drain. The first end phase change material layer may be vertically stacked at one end of the intermediate phase change material layer with respect to the intermediate phase change material layer, may be connected to one end of the 2D n-type channel semiconductor material layer, and may be provided between the first insulating material layer and the one inside surface among the inside surfaces that face toward the inner space of the outer dielectric area. The second end phase change material layer may be vertically stacked at an opposite end of the intermediate phase change material layer with respect to the intermediate phase change material layer, may be connected to one end of the 2D p-type channel semiconductor material layer, and may be provided between the second insulating material layer and the opposite inside surface among the inside surfaces that face toward the inner space of the outer dielectric area.

The vertical sidewall-shaped ternary CMOS device may further include a first spacer composed of an insulating material, the first spacer being stacked on the top of the common gate and the bottom of the 2D phase change material layer and provided between the first insulating material layer and the second insulating material layer and a second spacer composed of an insulating material, the second spacer being stacked on the bottom of the common gate and provided between the first insulating material layer and the second insulating material layer.

The vertical sidewall-shaped ternary CMOS device may further include a CMOS input terminal connected to the common gate and configured such that a common input voltage is input to the common gate and a CMOS output terminal that is connected to the common drain and that outputs a common output voltage.

The CMOS output terminal may output a maximum voltage having a constant magnitude when a voltage input to the CMOS input terminal is less than a first reference voltage, may output an intermediate voltage having a constant magnitude when the voltage input to the CMOS input terminal is greater than or equal to a second reference voltage and less than a third reference voltage, and may output no voltage when the voltage input to the CMOS input terminal is greater than or equal to a fourth reference voltage.

According to an embodiment, a method for manufacturing the vertical sidewall-shaped ternary CMOS device includes a step of connecting the common gate to the top of a second spacer composed of an insulating material, a step of depositing a first spacer composed of an insulating material on the top of the common gate, a step of depositing the 2D n-type channel semiconductor material layer on the second spacer, the common gate, and one end of the first spacer, a step of depositing the 2D p-type channel semiconductor material layer on the second spacer, the common gate, and an opposite end of the first spacer, a step of depositing the 2D phase change material layer on the top of the first spacer such that the 2D phase change material layer is perpendicular to the 2D n-type channel semiconductor material layer and the 2D p-type channel semiconductor material layer, and a step of connecting the common drain to the top of the 2D phase change material layer.

The method may further include a step of connecting the first source to an opposite side surface that faces away from the one side surface of the 2D n-type channel semiconductor material layer that faces the one end of the common gate, a step of connecting the second source to an opposite side surface that faces away from the one side surface of the 2D p-type channel semiconductor material layer that faces the opposite end of the common gate, and a step of depositing an outer dielectric area on the first source, the second source, and the 2D phase change material layer such that the outer dielectric area is in contact with the opposite side surface of the 2D n-type channel semiconductor material layer and the opposite side surface of the 2D p-type channel semiconductor material layer.

### BRIEF DESCRIPTION OF DRAWINGS

The above and other objects and features will become apparent from the following description with reference to the following figures, wherein like reference numerals refer to like parts throughout the various figures unless otherwise specified, and wherein:

FIG. 1 is a view illustrating a trench-shaped ternary CMOS device according to an embodiment;

FIG. 2 is a view illustrating a trench-shaped ternary CMOS device according to an embodiment;

FIG. 3 is a view illustrating a vertical sidewall-shaped ternary CMOS device according to an embodiment;

FIG. 4 is a view illustrating a vertical sidewall-shaped ternary CMOS device according to an embodiment;

FIG. 5 is a view illustrating 2D phase change materials;

FIG. 6 is a graph for explaining a 2D phase change material having a decreasing band gap depending on an increase in thickness;

FIG. 7 is a graph for explaining a 2D phase change material having an increasing conductivity depending on an increase in thickness;

FIG. 8 is a view for explaining three states implemented in a ternary inverter;

FIG. 9 is a view for explaining a ternary device whose circuit complexity depending on an increase in logic radix is decreased when compared to that in the related art;

FIG. 10 is a view for explaining a possibility of simplification of artificial neural network connection by introduction of a ternary device;

FIG. 11 is a circuit diagram illustrating a trench-shaped ternary CMOS device or a vertical sidewall-shaped ternary CMOS device according to an embodiment;

FIG. 12 is a graph depicting a current flowing in the trench-shaped ternary CMOS device or the vertical sidewall-shaped ternary CMOS device depending on a voltage applied to a gate; and

FIG. 13 is a graph depicting input/output characteristics of the trench-shaped ternary CMOS device or the vertical sidewall-shaped ternary CMOS device according to an embodiment.

### DETAILED DESCRIPTION

In order to clarify the solutions of the present disclosure to the problems, the configuration of the present disclosure will be described in detail with reference to the accompanying drawings, based on the embodiments of the present disclosure. In adding the reference numerals to the components of each drawing, it should be noted that the identical or equivalent component is designated by the identical numeral even when they are displayed on other drawings, and when any drawing is explained, a component depicted in another drawing may be recited, if necessary.

Meanwhile, directional terms such as upper side, lower side, one side, opposite side, and the like are used in relation to the orientations of the disclosed drawings. Since components of embodiments of the present disclosure may be positioned in various orientations, the directional terms are used for illustrative purposes and do not limit the orientations.

When a portion “includes” a component, it means that the portion further includes other components, not excluding the other components unless specifically stated otherwise. When a portion is “connected” to a component, it may mean not only that the corresponding portion is directly connected to the corresponding component, but also that the corresponding portion is indirectly connected to the corresponding component with another component therebetween.

The terms such as first, second, and the like are used to distinguish one component from another component, and the components are not limited by the above-mentioned terms. The terms of a singular form include plural forms unless the context clearly makes an exception.

In steps, identification numerals are used for convenience of description. The identification numerals do not describe the order of the steps, and the steps may be performed differently from the specified order unless the context clearly states a specific order.

Hereinafter, embodiments of the present disclosure will be described in more detail with reference to the accompanying drawings. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art. In the drawings, the dimensions of components are exaggerated for clarity of illustration.

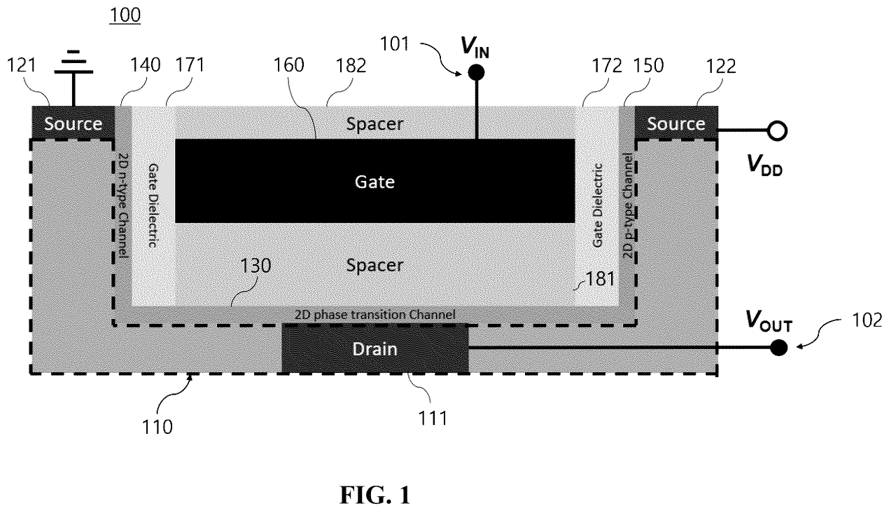

FIG. 1 is a view illustrating a trench-shaped ternary CMOS device according to an embodiment.

Referring to FIG. 1, the trench-shaped ternary CMOS device 100 may include an outer dielectric area 110 having a trench shape, and a 2D phase change material layer 130, a 2D n-type channel semiconductor material layer 140, a 2D p-type channel semiconductor material layer 150, and a common gate 160 that are stacked in an inner space of the outer dielectric area 110.

The trench-shaped ternary CMOS device 100 may be a CMOS device capable of performing ternary operations, unlike a conventional CMOS device that generally performs binary operations.

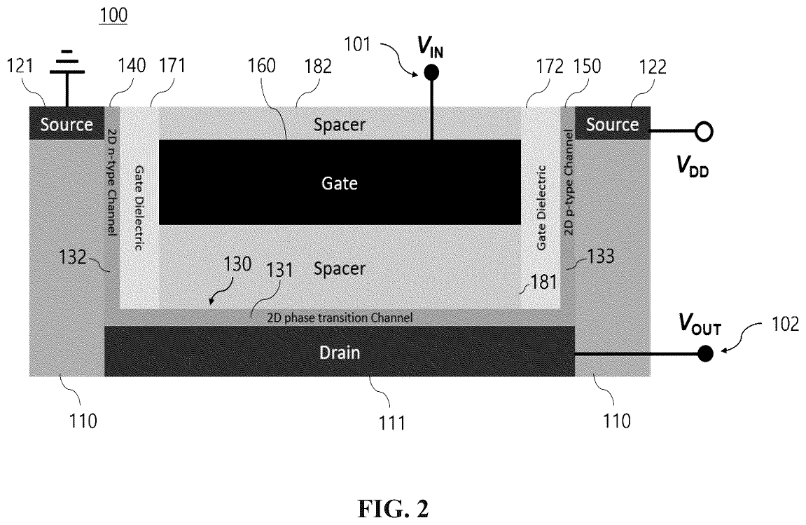

FIG. 2 is a view illustrating components of a trench-shaped ternary CMOS device according to an embodiment.

Referring to FIGS. 1 and 2, the trench-shaped ternary CMOS device 100 may include a CMOS input terminal 101, a CMOS output terminal 102, an outer dielectric area 110, a common drain 111, a first source 121, a second source 122, a 2D phase change material layer 130, a 2D n-type channel semiconductor material layer 140, a 2D p-type channel semiconductor material layer 150, a common gate 160, a first insulating material layer 171, a second insulating material layer 172, a first spacer 181, and a second spacer 182.

The 2D phase change material layer 130 may be composed of a 2D phase change material.

The 2D phase change material may be a material that, if a MOSFET device with the corresponding 2D phase change material as a channel is manufactured, allows the corresponding device to conduct a constant current irrespective of an input voltage applied to a gate.

The common drain 111 may be provided at the bottom of the trench-shaped ternary CMOS device 100.

The 2D phase change material layer 130 may be composed of a 2D phase change material. The 2D phase change material layer 130 may be stacked on the top of the common drain 111.

The common gate 160 may be provided over the 2D phase change material layer 130. The common gate 160 may be spaced apart from the 2D phase change material layer 130 by an insulating material.

The 2D n-type channel semiconductor material layer 140 may be vertically stacked with respect to the 2D phase change material layer 130 and may be connected to one end of the 2D phase change material layer 130. One side surface of the 2D n-type channel semiconductor material layer 140 may face one end of the common gate 160.

The 2D p-type channel semiconductor material layer 150 may be vertically stacked with respect to the 2D phase change material layer 130 and may be connected to an opposite end of the 2D phase change material layer 130. One side surface of the 2D p-type channel semiconductor material layer 150 may face an opposite end of the common gate 160.

The 2D semiconductor material layers may be composed of a 2D semiconductor material having a characteristic that it changes into a conductor by a voltage change without separate doping.

The 2D semiconductor material may be transition metal dichalcogenides (TMDCs) and may have a structure consisting of one transition metal element and two chalcogen elements. The 2D semiconductor material may have a layered structure and may mean a single layer or multiple layers of a crystalline material made of an atomic layer.

The 2D semiconductor material may have the characteristics of a non-conductor at ordinary time. However, when an electric field is applied, the 2D semiconductor material may exhibit a characteristic that it changes into a conductor. That is, the 2D semiconductor material may be a material that exhibits a specific polarity only by a voltage change without separate doping.

The 2D n-type channel semiconductor material layer 140 may be composed of a 2D semiconductor material having a characteristic that it changes into an n-type conductor by a voltage change without separate doping.

The 2D p-type channel semiconductor material layer 150 may be composed of a 2D semiconductor material having a characteristic that it changes into a p-type conductor by a voltage change without separate doping.

The 2D n-type channel semiconductor material layer 140 may be an n channel of the CMOS. In this case, the 2D n-type channel semiconductor material layer 140 may be composed of MoS₂. However, the present disclosure is not limited thereto, and it is apparent that various materials capable of forming an n channel among 2D semiconductor materials are able to be used for the 2D n-type channel semiconductor material layer 140.

The 2D p-type channel semiconductor material layer 150 may be a p channel of the CMOS. In this case, the 2D p-type channel semiconductor material layer 150 may be composed of WSe₂. However, the present disclosure is not limited thereto, and it is apparent that various materials capable of forming a p channel among the 2D semiconductor materials are able to be used for the 2D p-type channel semiconductor material layer 150.

Referring to FIGS. 1 and 2, the first source 121 may be connected to a side surface of the 2D n-type channel semiconductor material layer 140. The first source 121 may be connected to an opposite side surface of the 2D n-type channel semiconductor material layer 140 that faces away from the one side surface of the 2D n-type channel semiconductor material layer 140 that faces the one end of the common gate 160. Meanwhile, the first source 121 is not limited to being connected to the side surface of the 2D n-type channel semiconductor material layer 140. For example, the first source 121 may be stacked on the 2D n-type channel semiconductor material layer 140 and the outer dielectric area 110, and as long as the first source 121 is capable of being connected to an end area of the 2D n-type channel semiconductor material layer 140, it does not matter how the first source 121 is stacked. The first source 121 may be electrically connected to a ground.

The second source 122 may be connected to a side surface of the 2D p-type channel semiconductor material layer 150. The second source 122 may be connected to an opposite side surface of the 2D p-type channel semiconductor material layer 150 that faces away from the one side surface of the 2D p-type channel semiconductor material layer 150 that faces the opposite end of the common gate 160. Meanwhile, the second source 122 is not limited to being connected to the side surface of the 2D p-type channel semiconductor material layer 150. For example, the second source 122 may be stacked on the 2D p-type channel semiconductor material layer 150 and the outer dielectric area 110, and as long as the second source 122 is capable of being connected to an end area of the 2D p-type channel semiconductor material layer 150, it does not matter how the second source 122 is stacked. The second source 122 may have a power supply voltage V_{DD} applied thereto.

The common gate 160 may have a common input voltage V_{IN} applied thereto.

The common drain 111 may output a common output voltage V_{OUT}.

The CMOS input terminal 101 may be connected to the common gate 160 and may be configured such that the same common input voltage V_{IN} is input to the common gate 160. The CMOS output terminal 102 may be connected to the common drain 111 and may output the common output voltage V_{OUT}.

The common drain 111, the first source 121, and the second source 122 may be formed by performing patterning through an exposure process and then depositing a metal through a deposition technique such as an E-beam evaporator.

The 2D phase change material layer 130 may serve as a resistor that limits a current flow irrespective of the magnitude of the common input voltage V_{IN} applied to the common gate 160. Specifically, the 2D phase change material layer 130 may serve as a resistor that limits the On-current flowing through the second source 122, the 2D p-type channel semiconductor material layer 150, the 2D n-type channel semiconductor material layer 140, and the first source 121.

The trench-shaped ternary CMOS device 100 may include the outer dielectric area 110. The outer dielectric area 110 may be composed of oxide or nitride.

The outer dielectric area 110 may include the common drain 111. The remaining areas of the outer dielectric area 110 other than the common drain 111 may be composed of an insulating material.

The outer dielectric area 110 may have an inner space formed therein. The 2D phase change material layer 130, the 2D n-type channel semiconductor material layer 140, the 2D p-type channel semiconductor material layer 150, and the common gate 160 may be stacked in the inner space of the outer dielectric area 110.

The first source 121 may be stacked on an upper surface of one end of the outer dielectric area 110.

The second source 122 may be stacked on an upper surface of an opposite end of the outer dielectric area 110.

The 2D n-type channel semiconductor material layer 140 may be stacked on one inside surface among inside surfaces of the outer dielectric area 110 that face toward the inner space.

The 2D p-type channel semiconductor material layer 150 may be stacked on an opposite inside surface among the inside surfaces of the outer dielectric area 110 that face toward the inner space.

The 2D phase change material layer 130 may be stacked on an upper surface of the outer dielectric area 110 that faces toward the inner space or an upper surface of the common drain 111.

The first insulating material layer 171 may be vertically stacked with respect to the 2D phase change material layer 130 so as to be located between the 2D n-type channel semiconductor material layer 140 and the common gate 160. The first insulating material layer 171 may be composed of oxide or nitride.

The first insulating material layer 171 may be connected to the one side surface of the 2D n-type channel semiconductor material layer 140 that faces the one end of the common gate 160, the one end of the common gate 160, and the top of the 2D phase change material layer 130.

The first insulating material layer 171 may serve to electrically insulate the 2D n-type channel semiconductor material layer 140 and the common gate 160 from each other.

The second insulating material layer 172 may be vertically stacked with respect to the 2D phase change material layer 130 so as to be located between the 2D p-type channel semiconductor material layer 150 and the common gate 160.

The second insulating material layer 172 may be connected to the one side surface of the 2D p-type channel semiconductor material layer 150 that faces the opposite end of the common gate 160, the opposite end of the common gate 160, and the top of the 2D phase change material layer 130.

The second insulating material layer 172 may serve to electrically insulate the 2D p-type channel semiconductor material layer 150 and the common gate 160 from each other.

The first insulating material layer 171, the second insulating material layer 172, and the outer dielectric area 110 may be composed of a high-k material (e.g., Al₂O₃ or HfO₂). The first insulating material layer 171 and the second insulating material layer 172 may be deposited through atomic layer deposition (ALD), but are not limited thereto.

The first spacer 181 may be composed of an insulating material. The first spacer 181 may be stacked on the top of the 2D phase change material layer 130 and the bottom of the common gate 160 and may be provided between the first insulating material layer 171 and the second insulating material layer 172. The second insulating material layer 172 may be composed of oxide or nitride.

The second spacer 182 may be composed of an insulating material. The second spacer 182 may be stacked on the top of the common gate 160 and may be provided between the first insulating material layer 171 and the second insulating material layer 172.

Referring to FIG. 2, the 2D phase change material layer 130 may include an intermediate phase change material layer 131, a first end phase change material layer 132, and a second end phase change material layer 133.

The intermediate phase change material layer 131 may be stacked on the upper surface of the common drain 111.

The first end phase change material layer 132 may be vertically staked at one end of the intermediate phase change material layer 131 with respect to the intermediate phase change material layer 131.

The first end phase change material layer 132 may be connected to one end of the 2D n-type channel semiconductor material layer 140. The first end phase change material layer 132 may be provided between the one inside surface among the inside surfaces facing toward the inner space of the outer dielectric area 110 and the first insulating material layer 171.

The second end phase change material layer 133 may be vertically staked at an opposite end of the intermediate phase change material layer 131 with respect to the intermediate phase change material layer 131.

The second end phase change material layer 133 may be connected to one end of the 2D p-type channel semiconductor material layer 150 and may be provided between the opposite inside surface among the inside surfaces facing toward the inner space of the outer dielectric area 110 and the second insulating material layer 172.

As described above, the 2D phase change material layer 130 is not simply composed of a flat layer, but may be vertically stacked at the opposite ends. Accordingly, the overall horizontal width may be reduced while the performance of the trench-shaped ternary CMOS device 100 is maintained, and thus the degree of integration may be increased.

A method for manufacturing the trench-shaped ternary CMOS device 100 described above may include a step of connecting the first source 121 to the upper surface of the one end of the outer dielectric area 110 and a step of connecting the second source 122 to the upper surface of the opposite end of the outer dielectric area 110.

The method for manufacturing the trench-shaped ternary CMOS device 100 may include a step of depositing the 2D phase change material layer 130 on the top of the outer dielectric area 110 that faces toward the inner space of the outer dielectric area 110.

The method for manufacturing the trench-shaped ternary CMOS device 100 may include a step of depositing the 2D n-type channel semiconductor material layer 140 on the one inside surface among the inside surfaces facing toward the inner space and a step of depositing the 2D p-type channel semiconductor material layer 150 on the opposite inside surface among the inside surfaces facing toward the inner space.

The method for manufacturing the trench-shaped ternary CMOS device 100 may further include a step of depositing the first spacer 181, which is composed of an insulating material, on the top of the 2D phase change material layer 130, a step of connecting the common gate 160 to the top of the first spacer 181, and a step of depositing the second spacer 182 on the top of the common gate 160.

Meanwhile, a ternary CMOS device according to an embodiment may have a shape other than a trench shape.

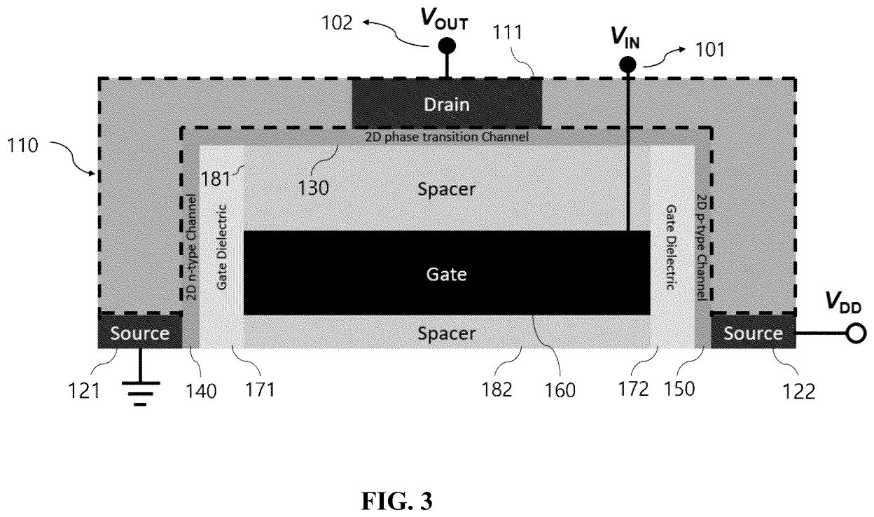

FIG. 3 is a view illustrating a vertical sidewall-shaped ternary CMOS device according to an embodiment.

Referring to FIG. 3, in the vertical sidewall-shaped ternary CMOS device, a 2D n-type channel semiconductor material layer 140 and a 2D p-type channel semiconductor material layer 150 may be stacked on opposite outside surfaces of vertical sidewalls of a second spacer 182, a common gate 160, and a first spacer 181 stacked one above another, and a 2D phase change material layer 130 may be stacked on the top of the vertical sidewalls.

In addition, an outer dielectric area 110 may be stacked to surround the 2D phase change material layer 130, the 2D n-type channel semiconductor material layer 140, and the 2D p-type channel semiconductor material layer 150 stacked on the vertical sidewalls. That is, the vertical sidewall-shaped ternary CMOS device may include the outer dielectric area 110 having a trench shape, and the 2D phase change material layer 130, the 2D n-type channel semiconductor material layer 140, the 2D p-type channel semiconductor material layer 150, and the common gate 160 that are stacked in an inner space of the outer dielectric area 110.

The vertical sidewall-shaped ternary CMOS device may be a CMOS device capable of performing ternary operations, unlike a conventional CMOS device that generally performs binary operations.

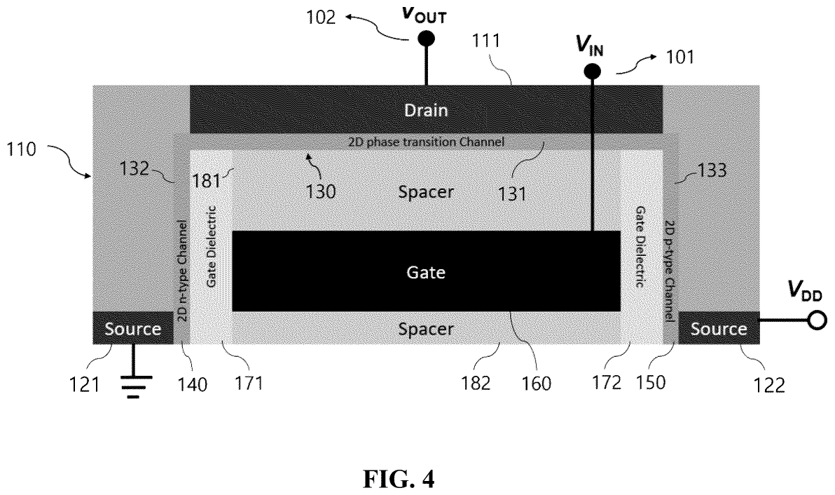

FIG. 4 is a view illustrating components of a vertical sidewall-shaped ternary CMOS device according to an embodiment.

Referring to FIGS. 3 and 4, the vertical sidewall-shaped ternary CMOS device may include a CMOS input terminal 101, a CMOS output terminal 102, an outer dielectric area 110, a common drain 111, a first source 121, a second source 122, a 2D phase change material layer 130, a 2D n-type channel semiconductor material layer 140, a 2D p-type channel semiconductor material layer 150, a common gate 160, a first insulating material layer 171, a second insulating material layer 172, a first spacer 181, and a second spacer 182.

The 2D phase change material layer 130 may be composed of a 2D phase change material.

The 2D phase change material may be a material that, if a MOSFET device with the corresponding 2D phase change material as a channel is manufactured, allows the corresponding device to conduct a constant current irrespective of an input voltage applied to a gate.

The common drain 111 may be provided at the top of the vertical sidewall-shaped ternary CMOS device.

The 2D phase change material layer 130 may be composed of a 2D phase change material. The 2D phase change material layer 130 may be stacked on the bottom of the common drain 111.

The common gate 160 may be provided under the 2D phase change material layer 130. The common gate 160 may be spaced apart from the 2D phase change material layer 130 by an insulating material.

The 2D n-type channel semiconductor material layer 140 may be vertically stacked with respect to the 2D phase change material layer 130 and may be connected to one end of the 2D phase change material layer 130. One side surface of the 2D n-type channel semiconductor material layer 140 may face one end of the common gate 160.

The 2D p-type channel semiconductor material layer 150 may be vertically stacked with respect to the 2D phase change material layer 130 and may be connected to an opposite end of the 2D phase change material layer 130. One side surface of the 2D p-type channel semiconductor material layer 150 may face an opposite end of the common gate 160.

The 2D semiconductor material layers may be composed of a 2D semiconductor material having a characteristic that it changes into a conductor by a voltage change without separate doping.

The 2D semiconductor material may be transition metal dichalcogenides (TMDCs) and may have a structure consisting of one transition metal element and two chalcogen elements. The 2D semiconductor material may have a layered structure and may mean a single layer or multiple layers of a crystalline material made of an atomic layer.

The 2D semiconductor material may have the characteristics of a non-conductor at ordinary time. However, when an electric field is applied, the 2D semiconductor material may exhibit a characteristic that it changes into a conductor. That is, the 2D semiconductor material may be a material that exhibits a specific polarity only by a voltage change without separate doping.

The 2D n-type channel semiconductor material layer 140 may be composed of a 2D semiconductor material having a characteristic that it changes into an n-type conductor by a voltage change without separate doping.

The 2D p-type channel semiconductor material layer 150 may be composed of a 2D semiconductor material having a characteristic that it changes into a p-type conductor by a voltage change without separate doping.

The 2D n-type channel semiconductor material layer 140 may be an n channel of the CMOS. In this case, the 2D n-type channel semiconductor material layer 140 may be composed of MoS₂. However, the present disclosure is not limited thereto, and it is apparent that various materials capable of forming an n channel among 2D semiconductor materials are able to be used for the 2D n-type channel semiconductor material layer 140.

The 2D p-type channel semiconductor material layer 150 may be a p channel of the CMOS. In this case, the 2D p-type channel semiconductor material layer 150 may be composed of WSe₂. However, the present disclosure is not limited thereto, and it is apparent that various materials capable of forming a p channel among the 2D semiconductor materials are able to be used for the 2D p-type channel semiconductor material layer 150.

Referring to FIGS. 3 and 4, the first source 121 may be connected to a side surface of the 2D n-type channel semiconductor material layer 140. The first source 121 may be connected to an opposite side surface of the 2D n-type channel semiconductor material layer 140 that faces away from the one side surface of the 2D n-type channel semiconductor material layer 140 that faces the one end of the common gate 160. The first source 121 may be electrically connected to a ground.

The second source 122 may be connected to a side surface of the 2D p-type channel semiconductor material layer 150. The second source 122 may be connected to an opposite side surface of the 2D p-type channel semiconductor material layer 150 that faces away from the one side surface of the 2D p-type channel semiconductor material layer 150 that faces the opposite end of the common gate 160. The second source 122 may have a power supply voltage V_{DD} applied thereto.

The common gate 160 may have a common input voltage V_{IN} applied thereto.

The common drain 111 may output a common output voltage V_{OUT}.

The CMOS input terminal 101 may be connected to the common gate 160 and may be configured such that the same common input voltage V_{IN} is input to the common gate 160. The CMOS output terminal 102 may be connected to the common drain 111 and may output the common output voltage V_{OUT}.

The common drain 111, the first source 121, and the second source 122 may be formed by performing patterning through an exposure process and then depositing a metal through a deposition technique such as an E-beam evaporator.

The 2D phase change material layer 130 may serve as a resistor that limits a current flow irrespective of the magnitude of the common input voltage V_{IN} applied to the common gate 160. Specifically, the 2D phase change material layer 130 may serve as a resistor that limits the On-current flowing through the second source 122, the 2D p-type channel semiconductor material layer 150, the 2D n-type channel semiconductor material layer 140, and the first source 121.

The vertical sidewall-shaped ternary CMOS device may include the outer dielectric area 110. The outer dielectric area 110 may be composed of oxide or nitride.

The outer dielectric area 110 may include the common drain 111. The remaining areas of the outer dielectric area 110 other than the common drain 111 may be composed of an insulating material.

The outer dielectric area 110 may have an inner space formed therein. The 2D phase change material layer 130, the 2D n-type channel semiconductor material layer 140, the 2D p-type channel semiconductor material layer 150, and the common gate 160 may be stacked in the inner space of the outer dielectric area 110.

The first source 121 may be stacked on a lower surface of one end of the outer dielectric area 110.

The second source 122 may be stacked on a lower surface of an opposite end of the outer dielectric area 110.

The 2D n-type channel semiconductor material layer 140 may be stacked on one inside surface among inside surfaces of the outer dielectric area 110 that face toward the inner space.

The 2D p-type channel semiconductor material layer 150 may be stacked on an opposite inside surface among the inside surfaces of the outer dielectric area 110 that face toward the inner space.

The 2D phase change material layer 130 may be stacked on a lower surface of the outer dielectric area 110 that faces toward the inner space or a lower surface of the common drain 111.

The first insulating material layer 171 may be vertically stacked with respect to the 2D phase change material layer 130 so as to be located between the 2D n-type channel semiconductor material layer 140 and the common gate 160. The first insulating material layer 171 may be composed of oxide or nitride.

The first insulating material layer 171 may be connected to the one side surface of the 2D n-type channel semiconductor material layer 140 that faces the one end of the common gate 160, the one end of the common gate 160, and the bottom of the 2D phase change material layer 130.

The first insulating material layer 171 may serve to electrically insulate the 2D n-type channel semiconductor material layer 140 and the common gate 160 from each other.

The second insulating material layer 172 may be vertically stacked with respect to the 2D phase change material layer 130 so as to be located between the 2D p-type channel semiconductor material layer 150 and the common gate 160.

The second insulating material layer 172 may be connected to the one side surface of the 2D p-type channel semiconductor material layer 150 that faces the opposite end of the common gate 160, the opposite end of the common gate 160, and the bottom of the 2D phase change material layer 130.

The second insulating material layer 172 may serve to electrically insulate the 2D p-type channel semiconductor material layer 150 and the common gate 160 from each other.

The first insulating material layer 171, the second insulating material layer 172, and the outer dielectric area 110 may be composed of a high-k material (e.g., Al₂O₃ or HfO₂). The first insulating material layer 171 and the second insulating material layer 172 may be deposited through atomic layer deposition (ALD), but are not limited thereto.

The first spacer 181 may be composed of an insulating material. The first spacer 181 may be stacked on the bottom of the 2D phase change material layer 130 and the top of the common gate 160 and may be provided between the first insulating material layer 171 and the second insulating material layer 172. The second insulating material layer 172 may be composed of oxide or nitride.

The second spacer 182 may be composed of an insulating material. The second spacer 182 may be stacked on the bottom of the common gate 160 and may be provided between the first insulating material layer 171 and the second insulating material layer 172.

Referring to FIG. 4, the 2D phase change material layer 130 may include an intermediate phase change material layer 131, a first end phase change material layer 132, and a second end phase change material layer 133.

The intermediate phase change material layer 131 may be stacked on the lower surface of the common drain 111.

The first end phase change material layer 132 may be vertically staked at one end of the intermediate phase change material layer 131 with respect to the intermediate phase change material layer 131.

The first end phase change material layer 132 may be connected to one end of the 2D n-type channel semiconductor material layer 140. The first end phase change material layer 132 may be provided between the one inside surface among the inside surfaces facing toward the inner space of the outer dielectric area 110 and the first insulating material layer 171.

The second end phase change material layer 133 may be vertically staked at an opposite end of the intermediate phase change material layer 131 with respect to the intermediate phase change material layer 131.

The second end phase change material layer 133 may be connected to one end of the 2D p-type channel semiconductor material layer 150 and may be provided between the opposite inside surface among the inside surfaces facing toward the inner space of the outer dielectric area 110 and the second insulating material layer 172.

As described above, the 2D phase change material layer 130 is not simply composed of a flat layer, but may be vertically stacked at the opposite ends. Accordingly, the overall horizontal width may be reduced while the performance of the vertical sidewall-shaped ternary CMOS device is maintained, and thus the degree of integration may be increased.

A method for manufacturing the vertical sidewall-shaped ternary CMOS device described above may include a step of connecting the common gate 160 to the top of the second spacer 182 composed of an insulating material and a step of depositing the first spacer 181, which is composed of an insulating material, on the top of the common gate 160.

The method for manufacturing the vertical sidewall-shaped ternary CMOS device may include a step of depositing the 2D n-type channel semiconductor material layer 140 on one side of the second spacer 182, the common gate 160, and the first spacer 181 and a step of depositing the 2D p-type channel semiconductor material layer 150 on an opposite side of the second spacer 182, the common gate 160, and the first spacer 181.

The method for manufacturing the vertical sidewall-shaped ternary CMOS device may include a step of stacking the 2D phase change material layer 130 on the top of the first spacer 181 such that the 2D phase change material layer 130 is perpendicular to the 2D n-type channel semiconductor material layer 140 and the 2D p-type channel semiconductor material layer 150.

The method for manufacturing the vertical sidewall-shaped ternary CMOS device may include a step of connecting the common drain 111 to the top of the 2D phase change material layer 130.

The method for manufacturing the vertical sidewall-shaped ternary CMOS device may include a step of connecting the first source 121 to the opposite side surface of the 2D n-type channel semiconductor material layer 140 that faces away from the one side surface of the 2D n-type channel semiconductor material layer 140 that faces the one end of the common gate 160.

The method for manufacturing the vertical sidewall-shaped ternary CMOS device may include a step of connecting the second source 122 to the opposite side surface of the 2D p-type channel semiconductor material layer 150 that faces away from the one side surface of the 2D p-type channel semiconductor material layer 150 that faces the opposite end of the common gate 160.

The method for manufacturing the vertical sidewall-shaped ternary CMOS device may further include a step of depositing the outer dielectric area 110 on the top of the first source 121, the top of the second source 122, and the top of the 2D phase change material layer 130 such that the outer dielectric area 110 is in contact with the opposite side surface of the 2D n-type channel semiconductor material layer 140 and the opposite side surface of the 2D p-type channel semiconductor material layer 150.

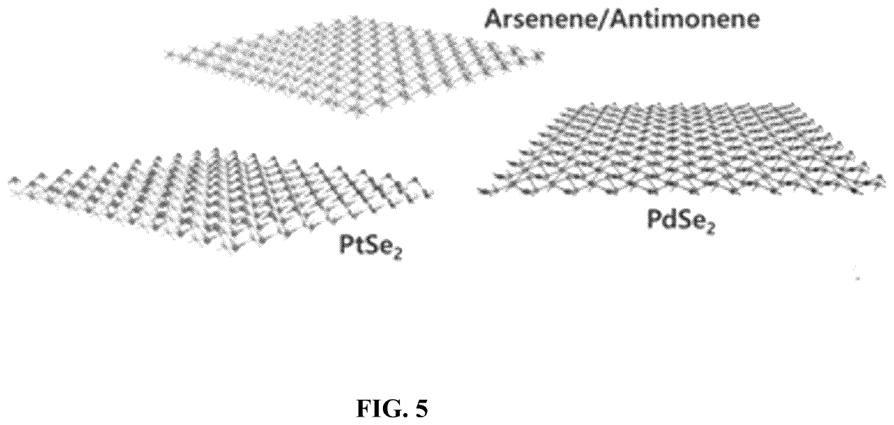

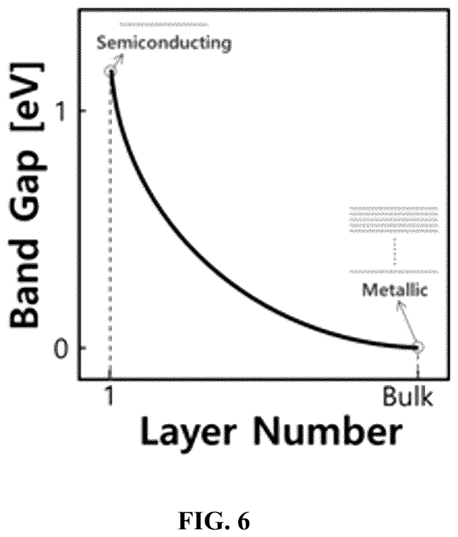

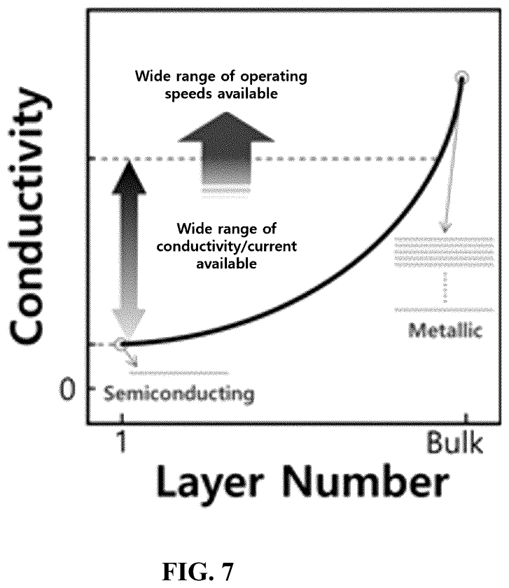

FIG. 5 is a view illustrating 2D phase change materials, FIG. 6 is a graph for explaining a 2D phase change material having a decreasing band gap depending on an increase in thickness, and FIG. 7 is a graph for explaining a 2D phase change material having an increasing conductivity depending on an increase in thickness.

Referring to FIGS. 5, 6, and 7, the 2D phase change material layer 130 may be composed of a 2D phase change material having a characteristic that a band gap is reduced as the thickness of a layer increases.

The 2D phase change material layer 130, which is a 2D phase change channel, may be composed of a 2D material illustrated in FIG. 5 that exhibits phase transition from a semiconductor to a conductor depending on a change in thickness.

The 2D phase change material layer 130 may be composed of transition metal dichalconenides (TMDs) having a characteristic that a band gap is reduced as the thickness of a layer increases. However, the 2D phase change material is not necessarily limited to the transition metal dichalconenides (TMDs).

The 2D phase change material layer 130 may be composed of at least one of platinum diselenide (PtSe₂) or palladium diselenide (PdSe₂) that is one of the above-described dichalcogenides. However, the 2D phase change material is not limited to the above-described materials.

For example, the 2D phase change material layer 130 may be composed of arsenene that is a 2D phase change material composed of a single element, in which the arsenene is an allotrope of arsenic (As) and has a 2D structure. Alternatively, the 2D phase change material layer may be composed of antimonene that is a 2D phase change material composed of a single element, in which the antimonene is an allotrope of antimony (Sb) and has a 2D structure.

As illustrated in FIG. 6, in the case of a monolayer, the 2D phase change materials, such as PDSe₂, PtSe₂, arsenene, and antimonene, may exhibit a phase transition phenomenon in which the 2D phase change materials have a band gap of 1 eV or more and accordingly have semiconducting characteristics but exhibit metallic characteristics due to a reduction of the band gap to zero depending on an increase in thickness.

When the above-described phase transition characteristics of the 2D phase change materials depending on the thickness change are used, a wide range of conductivity and current may be secured by adjusting the thickness as illustrated in FIG. 7. Accordingly, T-CMOS technology with a wide range of applications from ultra-low power to high performance may be implemented by supporting a wide range of operating speeds with the same device structure and process method.

In addition, since the 2D phase change materials are semiconductor materials that are able to be grown at low temperatures and subjected to upper integration processes under process conditions that do not deteriorate Si CMOS characteristics and reliability, the 2D phase change materials may be promising materials for monolithic 3D integration technology and may further improve the degree of integration of a device.

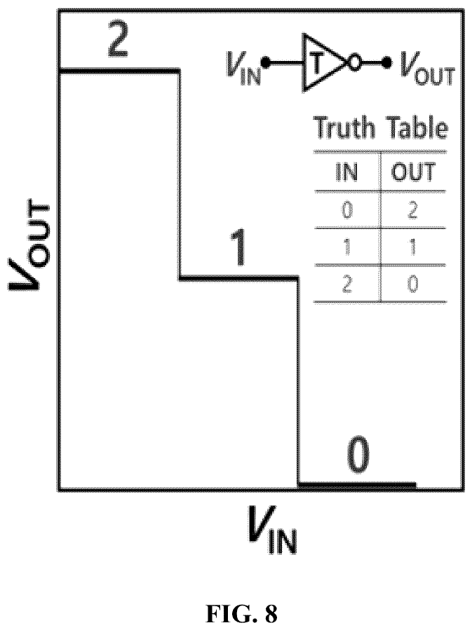

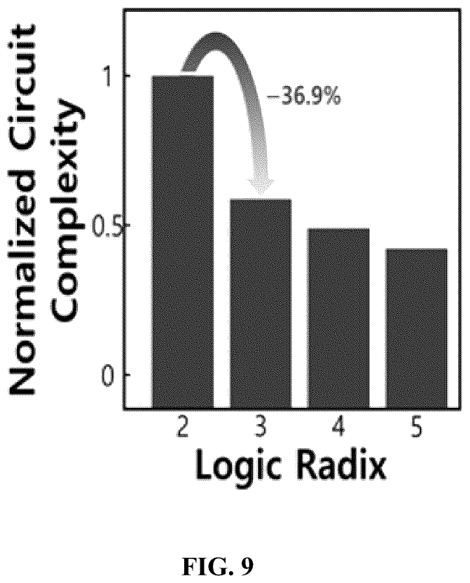

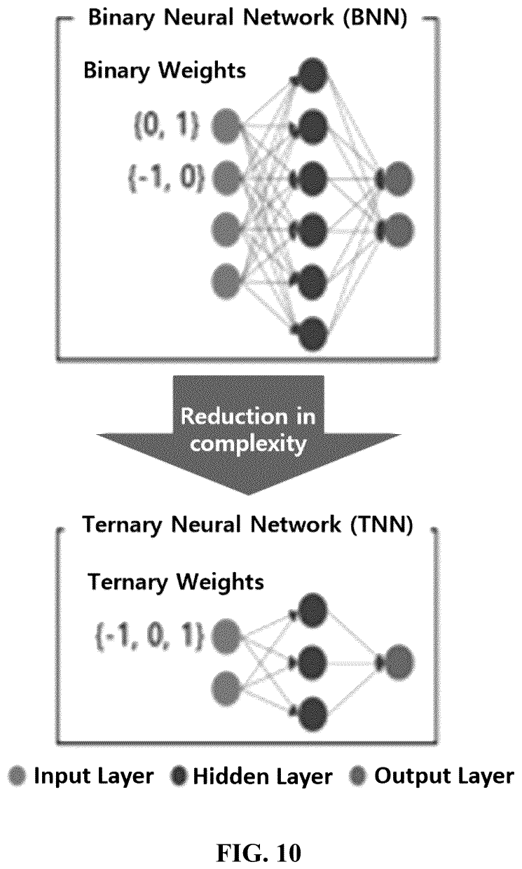

FIG. 8 is a view for explaining three states implemented in a ternary inverter, FIG. 9 is a view for explaining a ternary device whose circuit complexity depending on an increase in logic radix is decreased when compared to that in the related art, and FIG. 10 is a view for explaining a possibility of simplification of artificial neural network connection by introduction of a ternary device.

Referring to FIGS. 8, 9, and 10, it is possible to identify the advantages of a device using ternary operations compared to a device using conventional binary operations.

The ternary device illustrated in FIG. 8 may express information in the ternary system of 0, 1, and 2 to reduce the amount of information to be processed when compared to an existing binary device, thereby drastically improving a problem of power consumption.

When the representation of information is converted from the bit of the binary device to the trit of the ternary device, the voltage required for the state change in FIG. 8 may be half of that in the existing binary, and 2 bits may be expressed with 1 trit. Accordingly, the circuit complexity may be dramatically reduced as illustrated in FIG. 9, and thus power consumption may be drastically reduced.

In addition, in the implementation of an artificial neural network, which has been actively studied in recent years, a reduction in power consumption may be achieved by simplifying the circuit connection by introducing ternary weights {−1, 0, 1} instead of the conventional binary weights {0, 1} as illustrated in FIG. 10.

In order to express information in the ternary system having the above-described advantages, the implementation of the ternary inverter (T-Inverter) of FIG. 8 is essential. In the related art, various studies have been actively conducted to form VDD/2 in an intermediate state by distributing a drive voltage VDD, but this method has many problems.

For example, a technology using stepped current-voltage characteristics by multiple threshold voltages in a device ON state by implementing multiple threshold voltages by resonant tunneling from a Si Channel to a QD by forming the quantum dot (QD) on gate oxide in a Si MOSFET has difficulty in implementing a stable constant current due to a threshold voltage distribution problem caused by non-uniform QD formation. This has a problem in that a constant current is formed in the device ON state so that static power consumption in an additional state is very large. In addition, it is difficult to reduce power consumption by operating voltage (VDD) scaling due to the implementation of the multiple threshold voltages.

A technology that uses negative differential resistance of a device ON state implemented at the level of a small flake obtained by a mechanical exfoliation technique by using negative differential resistance by tunneling in a 2D material heterostructure has a problem in that a constant current is formed in the device ON state so that static power consumption in an additional state is very large. In addition, there is a problem that it is difficult to reduce power consumption by operating voltage (VDD) scaling due to the implementation of multiple threshold voltages.

A technology using stepped current-voltage characteristics by multiple threshold voltages in a device ON state by implementing multiple threshold voltages based on the mobility edge quantization effect principle using a ZnO composite has a problem in that a constant current is formed in the device ON state so that static power consumption in an additional state is very large. In addition, there is a problem that it is difficult to reduce power consumption by operating voltage (VDD) scaling due to the implementation of the multiple threshold voltages.

A technology that uses a constant current in a device OFF state by implementing a small constant current component by tunneling independent of a gate voltage by forming a local PN junction at the bottom of a channel in a Si MOSFET uses the small constant current in the device OFF state and therefore has a problem in that the technology is only suitable for ultra-low power applications. Accordingly, it may be desirable to implement a CMOS device capable of ternary operations in a new way.

An existing ternary CMOS (T-CMOS) device has a clear limitation in an application range, whereas the illustrated ternary CMOS device 100 may support a wide range of operating speeds and may be used for various purposes from ultra-low power to high performance.

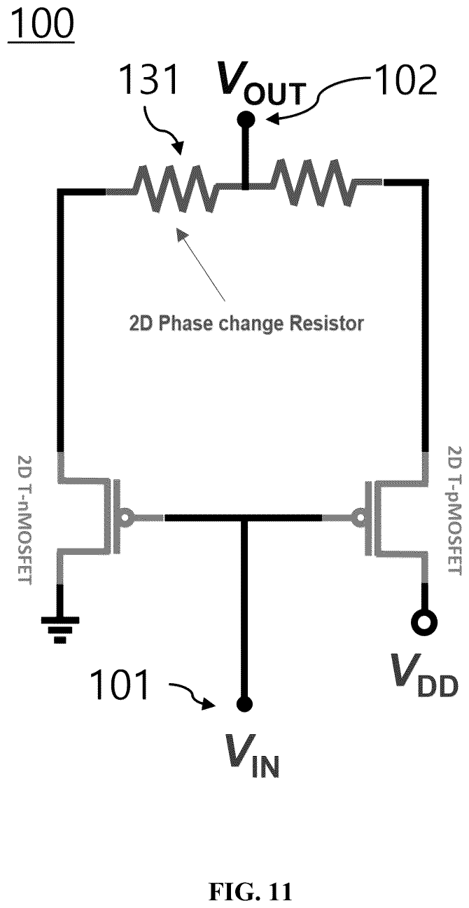

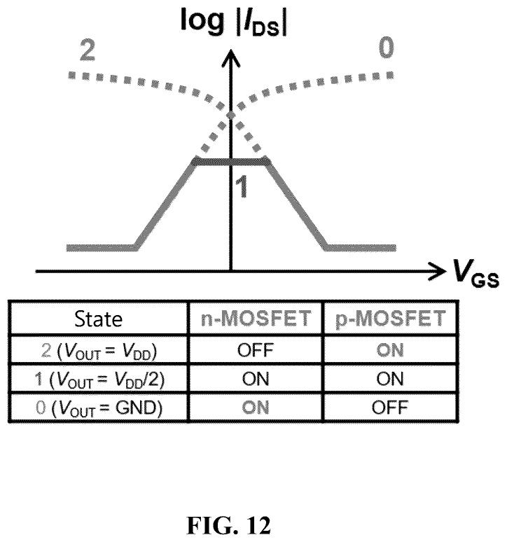

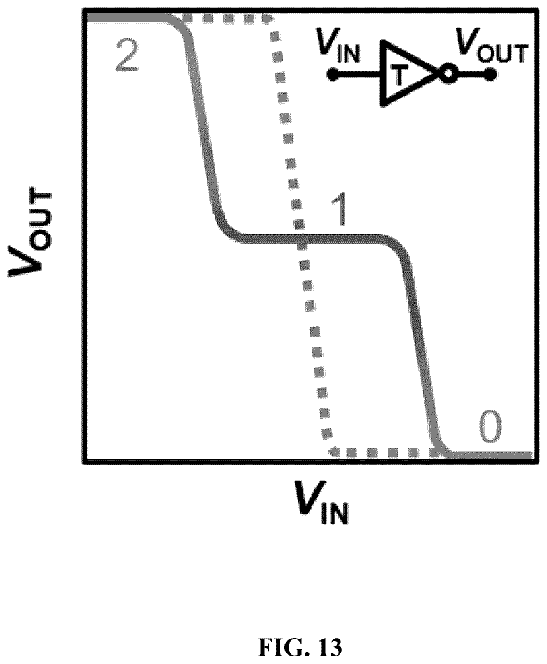

FIG. 11 is a circuit diagram illustrating a trench-shaped ternary CMOS device or a vertical sidewall-shaped ternary CMOS device according to an embodiment, FIG. 12 is a graph depicting a current flowing in the trench-shaped ternary CMOS device or the vertical sidewall-shaped ternary CMOS device depending on a voltage applied to a gate, and FIG. 13 is a graph depicting input/output characteristics of the trench-shaped ternary CMOS device or the vertical sidewall-shaped ternary CMOS device according to an embodiment.

Referring to FIGS. 11, 12, and 13, as can be seen from the illustrated I_{DS}−V_{GS} characteristics, the 2D phase change material layer 130 limits the On-current of the n/p MOSFETs while acting as a resistor. Accordingly, even when the MOSFETs are turned on, the current cannot increase beyond a certain level of constant current, and as illustrated, an intermediate state may be generated in the trench-shaped ternary CMOS device 100, that is, the T-CMOS inverter.

The trench-shaped ternary CMOS device 100 may use a constant current in a device ON state to implement an intermediate state of the ternary system. The used constant current may not be a current by Si-based junction tunneling, but may be a current flowing through the Schottky junction of source/drain metals and an undoped 2D material. The trench-shaped ternary CMOS device 100 according to an embodiment may more robustly and stably implement a constant current because there is no process dispersion problem caused by doping.

Referring to the I_{DS}−V_{GS} curve illustrated in FIG. 12, it can be confirmed that as the gate source voltage V_{GS} increases in the negative gate voltage range \textcircled{1}, the current I_{DS} flows through the 2D n-type channel semiconductor material layer 140, stops increasing at a specific point, and is saturated.

In addition, it can be confirmed that as the gate source voltage V_{GS} decreases in the positive gate voltage range \textcircled{2}, the current I_{DS} flows through the 2D p-type channel semiconductor material layer 150, stops increasing at a specific point, and is saturated.

Referring to FIG. 13, the input/output characteristics of the trench-shaped ternary CMOS device 100 and the vertical sidewall-shaped ternary CMOS device according to an embodiment may be identified.

When the voltage input to the CMOS input terminal 101 is less than a first reference voltage, the CMOS output terminal 102 may output a maximum voltage having a constant magnitude.

When the voltage input to the CMOS input terminal 101 is greater than or equal to a second reference voltage and less than a third reference voltage, the CMOS output terminal 102 may output an intermediate voltage having a constant magnitude.

Unlike the previous T-CMOS studies using tunneling current, the trench-shaped ternary CMOS device 100 and the vertical sidewall-shaped ternary CMOS device according to an embodiment may be ternary devices that utilize an effect that a 2D phase change channel under a common drain to which an output voltage is connected acts as a resistor to limit the On-current of each MOSFET.

When the voltage input to the CMOS input terminal 101 is greater than or equal to a fourth reference voltage, the CMOS output terminal 102 may be configured such that no voltage is output.

According to one aspect of the present disclosure, ternary operations may be performed.

According to another aspect of the present disclosure, the components may be stacked inside the trench-shaped outer dielectric area, and thus the degree of integration may be increased.

According to another aspect of the present disclosure, the ternary CMOS devices may support a wide range of operating speeds and thus may be used for various purposes from an ultra-low power environment to a high performance environment.

According to another aspect of the present disclosure, the ternary CMOS devices may be more robustly and stably implemented without a problem of process dispersion due to doping.

According to another aspect of the present disclosure, the degree of integration of the devices may be increased by using the semiconductor material capable of the upper integration process under the process condition that does not deteriorate the Si-based CMOS characteristics and the reliability.

Meanwhile, effects of the present disclosure are not limited to the aforementioned effects, and any other effects not mentioned herein will be clearly understood from the following description by those skilled in the art to which the present disclosure pertains.

The above description exemplifies the present disclosure. Furthermore, the above-mentioned contents describe embodiments of the present disclosure, and the present disclosure may be used in various other combinations, changes, and environments. That is, variations or modifications can be made to the present disclosure without departing from the spirit and scope of the present disclosure that is disclosed in the specification, the equivalent scope to the written disclosures, and/or the technical or knowledge range of those skilled in the art. The written embodiments describe the best state for implementing the technical spirit of the present disclosure, and various changes required in specific applications and purposes of the present disclosure can be made. Accordingly, the detailed description of the present disclosure is not intended to restrict the present disclosure in the disclosed embodiment state. In addition, it should be construed that the attached claims include other embodiments.

What is claimed is:

1. A trench-shaped ternary CMOS device comprising:
a common drain provided at the bottom;
a 2D phase change material layer composed of a 2D phase change material and stacked on the top of the common drain;
a common gate provided over the 2D phase change material layer;
a 2D n-type channel semiconductor material layer vertically stacked with respect to the 2D phase change material layer and connected to one end of the 2D phase change material layer, the 2D n-type channel semiconductor material layer having one side surface configured to face one end of the common gate; and
a 2D p-type channel semiconductor material layer vertically stacked with respect to the 2D phase change material layer and connected to an opposite end of the 2D phase change material layer, the 2D p-type channel semiconductor material layer having one side surface configured to face an opposite end of the common gate.

2. The trench-shaped ternary CMOS device of claim 1, wherein the 2D n-type channel semiconductor material layer is composed of a 2D semiconductor material having a characteristic of changing into an n-type conductor by a voltage change without separate doping, and
wherein the 2D p-type channel semiconductor material layer is composed of a 2D semiconductor material having a characteristic of changing into a p-type conductor by a voltage change without separate doping.

3. The trench-shaped ternary CMOS device of claim 1, wherein the 2D phase change material layer is composed of a 2D phase change material having a characteristic that a band gap is reduced as a thickness of a layer increases.

4. The trench-shaped ternary CMOS device of claim 3, wherein the 2D phase change material layer is composed of transition metal dichalcogenides (TDMs) having a characteristic that a band gap is reduced as a thickness of a layer increases.

5. The trench-shaped ternary CMOS device of claim 3, wherein the 2D phase change material layer is composed of at least one of platinum diselenide (PtSe₂) or palladium diselenide (PdSe₂).

6. The trench-shaped ternary CMOS device of claim 3, wherein the 2D phase change material layer is composed of at least one of arsenene or antimonene, wherein the arsenene is a 2D phase change material composed of a single element and has a 2D structure while being an allotrope of arsenic (As), and the antimonene is a 2D phase change material composed of a single element and has a 2D structure while being an allotrope of antimony (Sb).

7. The trench-shaped ternary CMOS device of claim 1, further comprising:
a first source connected to an opposite side surface configured to face away from the one side surface of the 2D n-type channel semiconductor material layer, the one side surface being configured to face the one end of the common gate; and
a second source connected to an opposite side surface configured to face away from the one side surface of the 2D p-type channel semiconductor material layer, the one side surface being configured to face the opposite end of the common gate.

8. The trench-shaped ternary CMOS device of claim 7, wherein the 2D phase change material layer serves as a resistor configured to limit On-current flowing through the second source, the 2D p-type channel semiconductor material layer, the 2D n-type channel semiconductor material layer, and the first source.

9. The trench-shaped ternary CMOS device of claim 7, further comprising:
an outer dielectric area having an inner space formed therein in which the 2D phase change material layer, the 2D n-type channel semiconductor material layer, the 2D p-type channel semiconductor material layer, and the common gate are stacked, the outer dielectric area including the common drain.

10. The trench-shaped ternary CMOS device of claim 9, wherein the first source is stacked on an upper surface of one end of the outer dielectric area,
wherein the second source is stacked on an upper surface of an opposite end of the outer dielectric area;
wherein the 2D n-type channel semiconductor material layer is stacked on one inside surface among inside surfaces of the outer dielectric area configured to face toward the inner space,
wherein the 2D p-type channel semiconductor material layer is stacked on an opposite inside surface among the inside surfaces of the outer dielectric area configured to face toward the inner space, and
wherein the 2D phase change material layer is stacked on an upper surface of the outer dielectric area configured to face toward the inner space or an upper surface of the common drain.

11. The trench-shaped ternary CMOS device of claim 10, further comprising:
a first insulating material layer vertically stacked with respect to the 2D phase change material layer so as to be located between the 2D n-type channel semiconductor material layer and the common gate, wherein the first insulating material layer is connected to the one end of the common gate, the one side surface of the 2D n-type channel semiconductor material layer configured to face the one end of the common gate, and the top of the 2D phase change material layer; and
a second insulating material layer vertically stacked with respect to the 2D phase change material layer so as to be located between the 2D p-type channel semiconductor material layer and the common gate, wherein the second insulating material layer is connected to the opposite end of the common gate, the one side surface of the 2D p-type channel semiconductor material layer configured to face the opposite end of the common gate, and the top of the 2D phase change material layer.

12. The trench-shaped ternary CMOS device of claim 11, wherein the 2D phase change material layer includes:
an intermediate phase change material layer stacked on the upper surface of the common drain;
a first end phase change material layer vertically stacked at one end of the intermediate phase change material layer with respect to the intermediate phase change material layer and connected to one end of the 2D n-type channel semiconductor material layer, the first end phase change material layer being provided between the first insulating material layer and the one inside surface among the inside surfaces configured to face toward the inner space of the outer dielectric area; and
a second end phase change material layer vertically stacked at an opposite end of the intermediate phase change material layer with respect to the intermediate phase change material layer and connected to one end of the 2D p-type channel semiconductor material layer, the second end phase change material layer being provided between the second insulating material layer and the opposite inside surface among the inside surfaces configured to face toward the inner space of the outer dielectric area.

13. The trench-shaped ternary CMOS device of claim 11, further comprising:
a first spacer composed of an insulating material, the first spacer being stacked on the top of the 2D phase change material layer and the bottom of the common gate and provided between the first insulating material layer and the second insulating material layer; and
a second spacer composed of an insulating material, the second spacer being stacked on the top of the common gate and provided between the first insulating material layer and the second insulating material layer.

14. The trench-shaped ternary CMOS device of claim 7, further comprising:
a CMOS input terminal connected to the common gate and configured such that a common input voltage is input to the common gate; and
a CMOS output terminal connected to the common drain and configured to output a common output voltage.

15. The trench-shaped ternary CMOS device of claim 14, wherein the CMOS output terminal is configured to:
output a maximum voltage having a constant magnitude when a voltage input to the CMOS input terminal is less than a first reference voltage;
output an intermediate voltage having a constant magnitude when the voltage input to the CMOS input terminal is greater than or equal to a second reference voltage and less than a third reference voltage; and
output no voltage when the voltage input to the CMOS input terminal is greater than or equal to a fourth reference voltage.

16. A method for manufacturing the trench-shaped ternary CMOS device of claim 15, the method comprising:
a step of connecting the first source to an upper surface of one end of an outer dielectric area having an inner space formed therein and including the common drain;
a step of connecting the second source to an upper surface of an opposite end of the outer dielectric area;
a step of depositing the 2D phase change material layer on the top of the outer dielectric area configured to face toward the inner space of the outer dielectric area;
a step of depositing the 2D n-type channel semiconductor material layer on one inside surface among inside surfaces configured to face toward the inner space; and
a step of depositing the 2D p-type channel semiconductor material layer on an opposite inside surface among the inside surfaces configured to face toward the inner space.

17. The method of claim 16, further comprising:
a step of depositing a first spacer composed of an insulating material on the top of the 2D phase change material layer;
a step of connecting the common gate to the top of the first spacer; and
a step of depositing a second spacer on the top of the common gate.
